(19) United States
(12) Patent Application Publication
(10) Pub. No.: US 2007/0064961 A1
(43) Pub. Date: Mar. 22, 2007

(54) Audio control system and audio control method thereof

(75) Inventors: Ying-Feng Jiang, Shanghai City (TW); David Ho, Taipei (TW)

Correspondence Address: BIRCH STEWART KOLASCH & BIRCH, PO BOX 747, FALLS CHURCH, VA, 22040-0747, US

(73) Assignee: Inventec Appliances Corp.

(21) Appl. No.: 11/523,649

(22) Filed: Sep. 20, 2006

(30) Foreign Application Priority Data
Sep. 21, 2005 (TW) 94132717

(51) Int. Cl. H03G 3/00; H03G 9/00

(52) U.S. Cl. 381/104; 381/110; 381/102

(57) ABSTRACT

An audio control system includes: a receiving unit for receiving an analog signal, a memory unit for storing a reference table for recording a predetermined signal data, a control unit for converting the analog signal into a digital signal and conducting a comparison of the digital signal with respect to the reference so as to adjust a corresponding gain of the digital signal according to said predetermined signal data, thereby generating a voice signal according to said corresponding gain. An output unit is used for outputting the voice signal.

### FIELD OF THE INVENTION

The invention relates to an audio control system and method for controlling the volume of an audio, and more particularly to the audio control system and method thereof for use in an electronic communication device.

### BACKGROUND OF THE INVENTION

Nowadays, it is very common to contact one another by means of electronic communication devices, such as mobile phones. During the operation, the mobile phone may suffer a little quantity defect due to certain reasons. For example, the volume of the speech is lowered in case the handset (he or she holding) is taken away from the user's mouth or ear.

In the prior art, a distance detector is implemented within the mobile phone in order to improve the aforementioned disadvantage. FIG. 1 shows a conventional mobile phone 11 and a voice-generating source 13 that is kept apart from the conventional mobile phone 11 at a predetermined distance 14. The voice-generating source 13 is capable of producing voice, such as speeches. The conventional mobile phone 11 is equipped with a distance detector 12 which is capable of detecting the voice generated from the voice-generating source 13 so as to result in a distance information corresponding to the predetermined distance 14, thereby generating a voice signal to adjust the volume of the voice. The longer the predetermined distance 14 of the conventional mobile phone 11 kept away from the voice-generating source 13 is, the distance detector 12 will automatically raises the volume of the voice. The volume of the voice is lowered when the voice-generating source 13 is brought toward the conventional mobile phone 11 (hence the distance detector 12).

However, installation of the distance detector 12 in the conventional mobile phone 11 results in extra process for the manufacturers and consequently causes increased manufacturing cost.

### SUMMARY OF THE INVENTION

Therefore, it is the object of the present invention to provide an audio control system and method thereof in which a reference table is substituted for the sake of the distance detector for controlling and adjusting the volume of the voice.

According to the present invention, an audio control system for use in an electronic communication device is provided and includes: a receiving unit for receiving an analog signal, a memory unit for storing a reference table for recording a predetermined signal data, a control unit for converting the analog signal into a digital signal and conducting a comparison of the digital signal with respect to the reference table so as to adjust a corresponding gain of the digital signal according to the predetermined signal data, thereby generating a voice signal according to the corresponding gain, and an output unit for outputting the voice signal.

In a second aspect of the present invention, an audio control method for use in an electronic device is provided and includes the steps: (a) receiving an analog signal via a receiving unit, (b) storing a reference table in a memory unit for recording a predetermined signal data, (c) a control unit for converting the analog signal into a digital signal and conducting a comparison of the digital signal with respect to the reference table so as to adjust a corresponding gain of the digital signal according to the predetermined signal data, thereby generating a voice signal according to the corresponding gain, and (d) outputting the voice signal by an output unit.

### BRIEF DESCRIPTION OF THE DRAWING

Other features and advantages of this invention will become more apparent in the following detailed description of the preferred embodiments of this invention, with reference to the accompanying drawings, in which:

FIG. 1 shows a conventional mobile phone and a voice-generating source;

FIG. 2 is a block diagram representing an audio control system of the present invention;

FIG. 3 is a flow chart illustrating the method of the present invention for controlling the volume of an audio;

FIG. 4 shows a reference table employed in the audio control system of the present invention; and

FIG. 5 shows a circuit diagram for a control unit employed in the audio control system of the present invention.

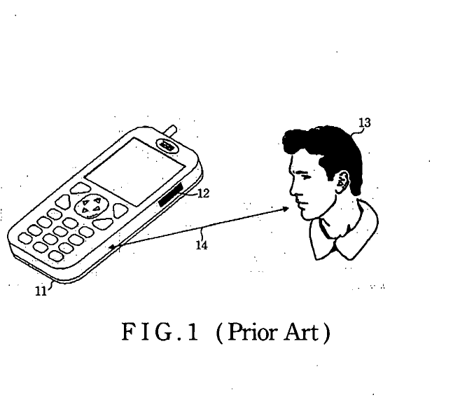

### DETAILED DESCCRIPTIONS OF THE PREFERRED EMBODIMENTS

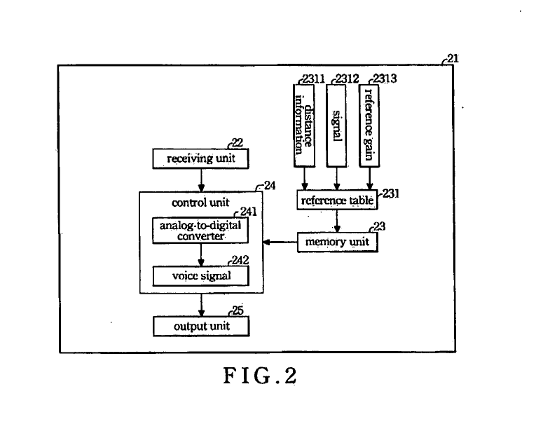

FIG. 2 shows a block diagram illustrating the audio control system of the present invention. The audio control system 21 is used in an electronic communication device, such as a mobile phone. The audio control system 21 includes a receiving unit 22, a memory unit 23, a control unit 24 and an output unit 25. The control unit 24 includes an analog-to-digital converter 241 for converting an analog signal into a digital signal. The receiving unit 22 is used for receiving an external analog signal. The analog signal in fact is an external voice signal. The analog-to-digital converter 241 converts the analog signal into a 16 bit digital signal. A reference table 231 is stored within the memory unit or device 23 in advance for recording a predetermined signal data. The predetermined signal data includes at least one distance column for recording a plurality of the distance information 2311, a signal column for recording a plurality of the corresponding signals 2312 and a value column for recording values of the plurality of reference gain 2313. The control unit 24 conducts a comparison of the digital signal with respect to the reference table 231 so as to adjust or alter a corresponding gain of the digital signal according to the predetermined signal data, thereby generating a voice signal 242 according to the corresponding gain. The voice signal 242 is outputted via the output unit 25, such as a microphone. The analog-to-digital converter 241 converts the analog signal into digital signal so as to enable the control unit 24 to adjust the corresponding gain. The distance information 2311 in fact is the distance between the electronic communication device and the voice-generating source, which generates the external voice signal (such as the user's mouth).

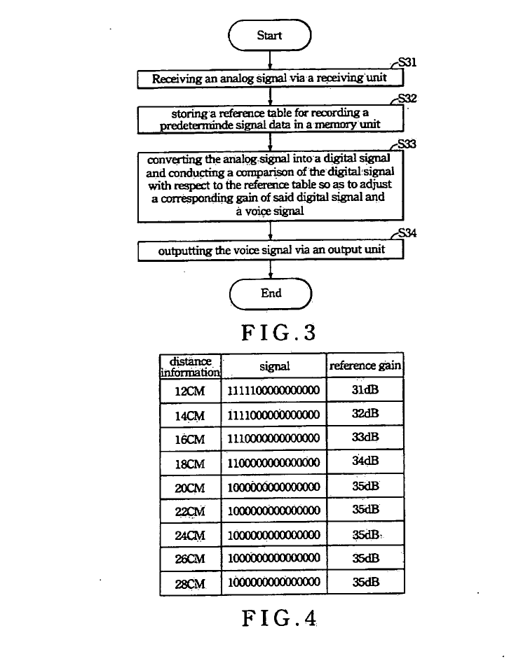

FIG. 3 shows a flow chart illustrating the audio control method utilized by the audio control system of the present invention. The audio control system is used in the electronic communication device, such a mobile phone, in order to control the volume of the speech. The audio control method accordingly includes the steps: (S31) receiving an analog signal via a receiving unit; (32) storing a reference table 231 for recording a predetermined signal data in a memory unit 23; (S33) a control unit for converting the analog signal into a digital signal and conducting a comparison of the digital signal with respect to the reference table so as to adjust and alter a corresponding gain of the digital signal according to the predetermined signal data, thereby generating a voice signal according to the corresponding gain; and (S34) outputting the voice signal by an output unit, such as a microphone.

FIG. 4 shows a reference table 231 that is stored within the memory device or unit of the audio control system of the present invention. The reference table 231 includes three columns, wherein the first denotes the distance column for recording a plurality of the distance information 2311, the second denotes the signal column for recording a plurality of the corresponding signals 2312 and the third denotes the value column for recording the values of the reference gain 2313. The reference gain 2313 varies with the corresponding signals 2312. The distance information denotes the distance between the voice-generating source and the electronic communication device. Each of the corresponding signals 2312 is a 16 bit digital signal of the binary numeral system to indicate the strength of the voice-generating source. The greater the voice strength of the signal 2312 is, the larger the value of the digital signal 2312 becomes. For example, the first distance 41 is 12 cm in the distance column 2311. After conducting a comparison with respect to the reference table 231 and in case of finding the corresponding digital signal matches the signal “1111100000000000” in the table 231, the reference gain is 31 db. The fifth distance 42 is 20 cm in the distance column 2311. After conducting a comparison with respect to the reference table 231 and in case of finding the corresponding digital signal matches the signal “100000000000000” in the table 231, the reference gain is 35 db. The eighth distance 43 is 26 cm in the distance column 2311. After conducting a comparison with respect to the reference table 231 and in case of finding corresponding digital signal matches the signal “1000000000000000” in the table 231, the reference gain is 35 db. From the aforementioned data, during the configuration of the reference table 231, the actual variation in the voice volume is considered. In case the voice-generating source is kept farther away beyond 20 cm, the resulted reference gain is the same as that of 20 cm distance. The corresponding signal 2312 becomes smaller as the voice-generating source is kept further away. It requires a greater adjustment in order to achieve the greater reference gain.

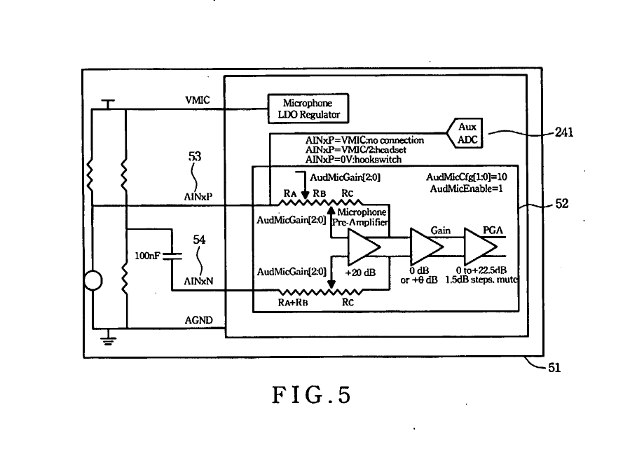

FIG. 5 shows a circuit diagram 51 representing the control unit employed in the audio control system of the present invention. The circuit diagram 51 includes at least an adjustable gain unit 52 and an analog-to-digital converter 241. The analog-to-digital converter 241 is capable of converting the analog signal into the digital signal in order to result in adjustment or variation of the reference gain. The gain unit 52 is used for altering the volume of the speech.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. An audio control system for use in an electronic communication device, comprising:
a receiving unit for receiving an analog signal;
a memory unit for storing a reference table for recording a predetermined signal data;
a control unit for converting said analog signal into a digital signal and conducting a comparison of said digital signal with respect to said reference table so as to adjust a corresponding gain of said digital signal according to said predetermined signal data, thereby generating a voice signal according to said corresponding gain; and
an output unit for outputting said voice signal.

2. The audio control system according to claim 1, wherein the electronic communication device is a mobile phone.

3. The audio control system according to claim 1, wherein said digital signal is a 16 bit digital signal.

4. The audio control system according to claim 1, wherein said analog signal is an external voice signal.

5. The audio control system according to claim 4, wherein said predetermined signal data includes a reference gain value, a distance information and a corresponding signal.

6. The audio control system according to claim 5, wherein said distance information is a distance between the electronic communication device and a voice-generating source, which generates said external voice signal.

7. The audio control system according to claim 1, wherein said control unit comprises an analog-to-digital converter.

8. The audio control system according to claim 7, wherein said analog-to-digital converter converts said analog signal into said digital signal for bringing about said corresponding gain.

9. The audio control system according to claim 1, wherein said output unit is a microphone.

10. An audio control method for use in an electronic device, comprising:
(a) receiving an analog signal via a receiving unit;
(b) storing a reference table for recording a predetermined signal data in a memory unit;
(c) a control unit converting said analog signal into a digital signal and conducting a comparison of said digital signal with respect to said reference table so as to adjust a corresponding gain of said digital signal according to said predetermined signal data, thereby generating a voice signal according to said corresponding gain; and
(d) an output unit outputting said voice signal.

11. The audio control method according to claim 10, wherein the electronic communication device is a mobile phone.

12. The audio control method according to claim 10, wherein said digital signal is a 16 bit digital signal.

13. The audio control method according to claim 10, wherein said analog signal is an external voice signal.

14. The audio control method according to claim 13, wherein said predetermined signal data includes a reference gain value, a distance information and a corresponding signal.

15. The audio control method according to claim 14, wherein said distance information is a distance between the electronic communication device and a voice-generating source,which generates said external voice signal.

16. The audio control method according to claim 10, wherein said control unit comprises an analog-to-digital converter.

17. The audio control method according to claim 16, wherein said analog-to-digital converter converts said analog signal into said digital signal for bringing about said corresponding gain.

18. The audio control method according to claim 10, wherein said output unit is a microphone.
